(19) United States
(12) Patent Application Publication
(10) Pub. No.: US 2025/0385197 A1
(43) Pub. Date: Dec. 18, 2025

(54) PACKAGING METHOD FOR GENERATING PARTITIONED EM-SHIELDING AND AN ELECTRONIC PACKAGING MODULE

(71) Applicant: Universal Global Technology (Shanghai) Co., Ltd., Shanghai (CN)

(72) Inventors: Yixin Wang, Shanghai (CN); Yao Li, Shanghai (CN); Song Ye, Shanghai (CN)

(73) Assignee: Universal Global Technology (Shanghai) Co., Ltd., Shanghai (CN)

(21) Appl. No.: 19/020,066

(22) Filed: Jan. 14, 2025

(30) Foreign Application Priority Data
Jun. 18, 2024 (CN) 202410790683.9

(51) Int. Cl. H01L 23/552; H01L 23/29

(52) U.S. Cl. CPC H01L 23/552; H01L 23/293

(57) ABSTRACT

The present application provides a packaging method for generating partitioned EM-shielding and an electronic packaging module. The method comprising: installing at least two electronic components on a substrate surface; installing a metal component for EM-shielding on the substrate between at least one group of adjacent electronic components; utilizing a hot mold to plastic-encapsulate the electronic components and the metal component to form a plastic encapsulation; wherein, when the mold is closed, the top of the metal component is tightly abutted to the upper mold of the hot mold, so that melted encapsulating material does not cover the top of the metal component. After the plastic-encapsulation, an EM-shielding layer is formed outside the plastic encapsulation, which also covers the surface of the metal component exposed from the plastic encapsulation. The present application reduces cost of electronic packaging modules, improves production efficiency and EM-shielding effect of the module.

### FIELD OF THE DISCLOSURE

The present application relates to a technical field of semiconductor packaging, and particularly to a packaging method for generating partitioned EM-shielding and an electronic packaging module.

### BACKGROUND

An electronic packaging module generally comprises a circuit board and a plurality of electronic components installed on the circuit board. These electronic components may be chips or passive components, etc. In addition, a plastic-encapsulation for enclosing the above electronic components is comprised to protect the electronic components.

Electronic products nowadays are configured to be thin, light and small, which results in a too high density of electronic components and circuits, which increases the problem of electromagnetic (EM) interference or EMI. Particularly, how to generate a multi-partition EM-shielding structure, i.e., to generate multiple EM-shielding partitions, on a circuit board where electronic components and circuits are densely distributed, has become a requirement of existing communication products.

Taking the SIP (System in Package) packaging module as an example, the current traditional operation mode of its EM-shielding technology is as follows: first, all electronic components are installed by SMT, and then plastic-encapsulated. After the plastic-encapsulating, laser grooves are generated at positions where EM-shielding is required, and then silver glue is filled and solidified in the grooved areas. And several units are obtained through cutting and separating. Single units are further sputtered to complete the entire EM-shielding. Wherein, the silver glue filled in the grooves and the sputtered coating together form a partitioned EM-shielding structure between the electronic components.

The above production process is complicated, the production cost is high, the quality is difficult to control, and there is a need to develop new technologies for replacement.

### SUMMARY OF THE INVENTION

One of the purposes of this application is to provide a packaging method for generating partitioned EM-shielding and an electronic packaging module to solve at least part of the problems existing in the prior art.

The technical solution provided by the present application is as follows:

A packaging method for generating partitioned EM-shielding, comprising:
installing at least two electronic components on a surface of a substrate;
installing a metal component for EM-shielding on the substrate between at least one group of adjacent said electronic components;
plastic-encapsulating the electronic components and the metal component utilizing a hot mold to form a plastic-encapsulation enclosing the electronic components and the metal component; wherein, when the mold is closed, a top of the metal component tightly abuts to an upper mold of the hot mold, so that melted encapsulating material does not cover the top of the metal component;
generating an EM-shielding layer outside the plastic-encapsulation after the plastic-encapsulating, wherein the EM-shielding layer also covers a surface of the metal component exposed through the plastic-encapsulation.

In some embodiments, a height of the metal component is greater than a height of a cavity formed when the hot mold is closed, and a hardness of the metal component is lower than a hardness of the upper mold of the hot mold.

In some embodiments, the metal component is provided with a U-shaped structure, and a first end of the U-shaped structure extends in a horizontal direction to constitute a shielding cover for the electronic components thereunder; and a second end of the U-shaped structure is used to contact the upper mold of the hot mold during the plastic-encapsulating.

In some embodiments, a top end of the second end of the metal component is provided with a bending section for contacting the upper mold of the hot mold during the plastic-encapsulating.

In some embodiments, a corner radius between the first end of the metal component and a wall is less than 0.2 mm.

In some embodiments, a wall thickness of the metal component is 50-300 um.

In some embodiments, an end for soldering or welding, which connects the metal component and the substrate, is provided with a bending structure, and a radius of the bending structure of the end for soldering or welding is greater than a wall thickness of the metal component.

In some embodiments, the metal component is a metal column or a metal wall.

In some embodiments, an interior of the metal column or the metal wall is hollow.

The present application also provides an electronic packaging module, manufactured by the packaging method for generating partitioned EM-shielding according to any one of the above embodiments, which comprises:
at least two electronic components installed on a surface of the substrate;
a metal component for EM-shielding, installed on the substrate and located between at least one group of adjacent said electronic components;
a plastic encapsulation, used to enclose the electronic components and the metal component, wherein a top of the metal component is exposed through the plastic encapsulation;
an EM-shielding layer, covering the plastic encapsulation and a surface of the metal component exposed through the plastic encapsulation.

The packaging method for generating partitioned EM-shielding and the electronic packaging module provided by the present application at least bring about the following beneficial effects: by utilizing a metal component instead of silver glue, the top of the metal component is tightly abutted to the upper mold of the plastic-encapsulating mold when the plastic-encapsulating mold is closed, so that melted plastic-encapsulating material will not cover the top of the metal component, so that the top of the metal component is exposed after the plastic-encapsulating. And then the metal component generates a partitioned EM-shielding structure together with an EM-shielding layer, which simplifies the production process, improves production efficiency, saves costs, and improves shielding performance.

### BRIEF DESCRIPTION OF THE DRAWINGS

The preferred embodiments will be described below in a clear and understandable manner in conjunction with the accompanying drawings to further illustrate the above-mentioned characteristics, technical features, advantages and implementation methods of a packaging method for generating partitioned EM-shielding and an electronic packaging module.

FIG. 1 is a flow chart of a packaging method for generating partitioned EM-shielding according to an embodiment of the present application;

FIGS. 2-3 are three-dimensional schematic diagrams of a columnar metal component;

FIGS. 4-6 are schematic diagrams of vertical cross sections of U-shaped metal components;

FIG. 7 is a schematic structural diagram of an electronic packaging module according to an embodiment of the present application.

### DESCRIPTION OF THE ILLUSTRATED EMBODIMENTS

To more clearly illustrate the embodiments of the present application or the technical solutions in the prior art, the specific implementation methods of the present application will be described below with reference to the accompanying drawings. Obviously, the accompanying drawings described below are only some embodiments of the present application. For ordinary technical persons in this field, other drawings and other implementation methods can be obtained based on these drawings without creative work.

To simplify the drawings, only the parts related to the present application are schematically shown in each figure, and they do not represent the actual structure of products. In addition, to simplify the drawings and facilitate understanding, in some figures, only one of the parts with a same structure or function is schematically drawn or marked. In this specification, “one” not only means “only one”, but also may mean “more than one”.

In one embodiment of the present application, as shown in FIG. 1, a packaging method for generating partitioned EM-shielding comprises:
Step S100: installing at least two electronic components on a surface of a substrate;
Step S200: installing a metal component for EM-shielding on the substrate between at least one group of adjacent electronic components;
Step S300: plastic-encapsulating the electronic components and the metal component utilizing a hot mold; wherein, when the mold is closed, the top of the metal component is tightly abutted to the upper mold of the hot mold, so that melted plastic-encapsulating material will not cover the top of the metal component;
Step S400: generating an EM-shielding layer outside the plastic-encapsulation, and the EM-shielding layer also covers the surface of the metal component exposed through the plastic-encapsulation.

Specifically, the metal component is used to shield EMI between electronic components. The material of the metal component is preferably copper or silver, and the surface thereof may be treated by nickel plating to further improve the EM-shielding effect.

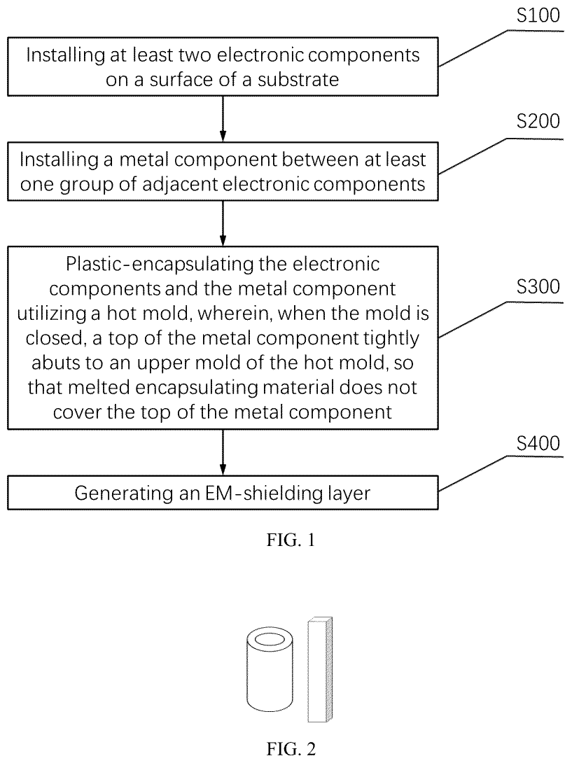

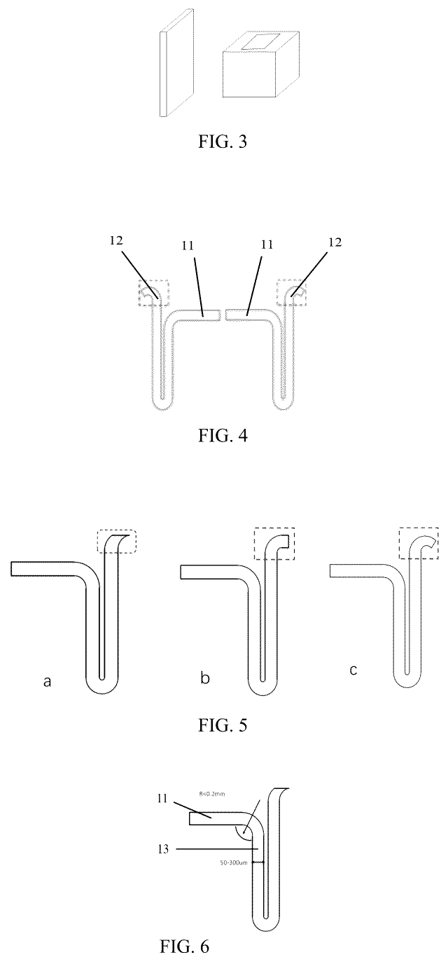

The metal component can be prepared in advance, and can be a metal column (as shown in FIG. 2) or a metal wall (as shown in FIG. 3), and the interior of the metal column or the metal wall can be hollow or solid. The metal component or metal components are provided at a position or at positions on the substrate where EM-shielding is required.

Step S100 and step S200 can be performed in stages or simultaneously. The installation method can be SMT or surface mounting technology, or other existing installation technologies. Placing a metal component or metal components together with the electronic components does not require additional machines, which improves efficiency and saves cost.

The height of the metal component is greater than the height of the cavity formed when the plastic-encapsulating mold is closed, and its hardness is lower than the hardness of the upper mold of the plastic-encapsulating mold. In this way, when the electronic components and the metal component are plastic-encapsulated, since the height of the metal component is greater than the height of the cavity, the top of the metal component can abut tightly against the upper mold of the plastic-encapsulating mold when the mold is closed.

The hot mold is a thermoplastic-encapsulating mold. During the encapsulating process, the substrate installed with the electronic components and the metal component or metal components is first placed into the mold, and then the encapsulating material is injected, the mold is heated, and the mold is closed. The encapsulating material softens and flows under high temperature and high pressure, filling the gaps in the mold, and forms a solid plastic-encapsulation after cooling. During the mold heating process, the temperature of the top of the metal component is the same as the upper mold temperature, which is higher, and the top of the metal component abuts tightly against the upper mold. When the encapsulating material is melted, it avoids the top of the metal component and does not cover the top of the metal component, so that the top of the metal component is exposed after the plastic-encapsulating.

After the plastic-encapsulating, an EM-shielding layer is formed on the surface of the plastic-encapsulation by sputtering, coating, printing, etc., and the EM-shielding layer also covers the surface of the metal component or metal components exposed through the plastic-encapsulation. The EM-shielding layer is electrically connected to the exposed surface of the metal component or metal components, achieving a partitioned EM-shielding structure.

In this embodiment, a metal component or metal components are used instead of silver glue, which eliminates the traditional laser grooving, silver glue filling and curing processes, simplifies the production process, improves production efficiency and saves cost. The metal component is installed onto the substrate by soldering or welding, which ensures that the metal component has a better electrical connection with the substrate, and avoids the problem of sensitivity degradation of the EM-shielding, and improves the shielding performance.

In one embodiment, as shown in FIG. 4, the metal component is provided with a U-shaped structure, wherein the first end 11 of the U-shaped structure extends horizontally to serve as a shielding cover for the electronic components thereunder. The second end 12 of the U-shaped structure is used to contact the upper mold of the hot mold during plastic-encapsulating.

The first end 11 of the U-shaped structure can be configured on the left side or on the right side, depending on actual needs. The advantage of this configuration is that when the plastic-encapsulating mold is pressed together, the first end 11 of the metal component remains horizontal, while the second end 12 is tightly abutted to the upper mold during the pressing and closing process, which does not affect the overall balance.

In one embodiment, the top end of the second end 12 of the metal component is provided with a bending section for contacting the upper mold of the hot mold during plastic-encapsulating.

FIG. 5 shows three different U-shaped metal components, wherein the differences being that the bending angles of the top end of the second end are different, but it is not limited to these bending angles. Bending configurations a and b are suitable for products with a thinner plastic-encapsulation, and bending configuration c is suitable for products with thicker a plastic-encapsulation.

Since the hardness of the metal component is lower than that of the mold, when the mold is closed, the top end of the second end of the metal component contacts the upper mold, bends and deforms, and abuts tightly against the upper mold.

Although the top end of the second end can also be configured as a straight section, being configured as a bending section is helpful to control the bending direction when the plastic-encapsulation is bent by the upper mold.

In one embodiment, as shown in FIG. 6, the corner radius between the first end 11 of the U-shaped metal component and the wall 13 is less than 0.2 mm. This minimizes the bending arc, increases the plane size of the first end of the metal component, and facilitates subsequent processes.

The thickness of the wall 13 of the metal component is controlled within the range of 50 to 300 um, so that the size of the metal component is reduced while ensuring the mechanical strength of the metal component, thereby saving space.

In one embodiment, the end for soldering or welding, which connects the metal component to the substrate, is provided with a bending structure, and the radius of the bending structure of the end for soldering or welding is greater than the wall thickness of the metal component. This enhances the soldering or welding ability of the metal component and improves the electrical connection between the metal component and the substrate.

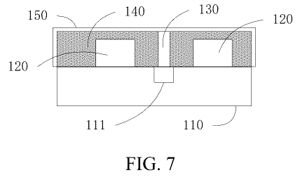

In one embodiment of the present application, as shown in FIG. 7, an electronic packaging module manufactured by the packaging method for generating partitioned EM-shielding according to an above embodiment comprises:
a substrate 110 comprising a ground pin 111;
at least two electronic components 120, installed onto the surface of the substrate 110;
a metal component 130 for EM-shielding, installed onto the ground pin 111 at the surface of the substrate 110 and located between at least one group of adjacent electronic components 120; wherein the metal component is electrically connected to the ground pin 111 of the substrate;
a plastic-encapsulation 140, used to enclose the electronic components and the metal component, wherein the top of the metal component 130 is exposed through the plastic-encapsulation 140;
an EM-shielding layer 150, covering the plastic-encapsulation 140 and the surface of the metal component 130 exposed through the plastic-encapsulation 140.

It should be noted that the above embodiments can be freely combined as needed. The above are only preferred embodiments of the present application. It should be pointed out, that for ordinary skilled in the art, several improvements and modifications can be made without departing from the principle of the present application, and these improvements and modifications should also be regarded as within the protection scope of the present application.

1. A packaging method for generating partitioned EM-shielding, characterized by comprising:
installing at least two electronic components on a surface of a substrate;
installing a metal component for EM-shielding on the substrate between at least one group of adjacent said electronic components;
plastic-encapsulating the electronic components and the metal component utilizing a hot mold to form a plastic-encapsulation enclosing the electronic components and the metal component; wherein, when the mold is closed, a top of the metal component tightly abuts to an upper mold of the hot mold, so that melted encapsulating material does not cover the top of the metal component;
generating an EM-shielding layer outside the plastic-encapsulation after the plastic-encapsulating, wherein the EM-shielding layer also covers a surface of the metal component exposed through the plastic-encapsulation.

2. The packaging method according to claim 1, characterized in that,
a height of the metal component is greater than a height of a cavity formed when the hot mold is closed, and a hardness of the metal component is lower than a hardness of the upper mold of the hot mold.

3. The packaging method according to claim 1, characterized in that,
the metal component is provided with a U-shaped structure, and a first end of the U-shaped structure extends in a horizontal direction to constitute a shielding cover for the electronic components thereunder; and a second end of the U-shaped structure is used to contact the upper mold of the hot mold during the plastic-encapsulating.

4. The packaging method according to claim 3, characterized in that,
a top end of the second end of the metal component is provided with a bending section for contacting the upper mold of the hot mold during the plastic-encapsulating.

5. The packaging method according to claim 3, characterized in that,
a corner radius between the first end of the metal component and a wall is less than 0.2 mm.

6. The packaging method according to claim 1, characterized in that,
a wall thickness of the metal component is 50-300 um.

7. The packaging method according to claim 1, characterized in that,
an end for soldering or welding, which connects the metal component and the substrate, is provided with a bending structure, and a radius of the bending structure of the end for soldering or welding is greater than a wall thickness of the metal component.

8. The packaging method according to claim 1, characterized in that,
the metal component is a metal column or a metal wall.

9. The packaging method according to claim 8, characterized in that,
an interior of the metal column or the metal wall is hollow.

10. An electronic packaging module, characterized by comprising:
a substrate;
at least two electronic components installed on a surface of the substrate;
a metal component for EM-shielding, installed on the substrate and located between at least one group of adjacent said electronic components;
a plastic encapsulation, used to enclose the electronic components and the metal component, wherein a top of the metal component is exposed through the plastic encapsulation; wherein the plastic encapsulation is generated utilizing a hot mold, wherein, when the mold is closed, a top of the metal component tightly abuts to an upper mold of the hot mold, so that melted encapsulating material does not cover the top of the metal component;
an EM-shielding layer, covering the plastic encapsulation and a surface of the metal component exposed through the plastic encapsulation.

11. The electronic packaging module according to claim 10, characterized in that,
a height of the metal component is greater than a height of a cavity formed when the hot mold is closed, and a hardness of the metal component is lower than a hardness of the upper mold of the hot mold.

12. The electronic packaging module according to claim 10, characterized in that,
the metal component is provided with a U-shaped structure, and a first end of the U-shaped structure extends in a horizontal direction to constitute a shielding cover for the electronic components thereunder; and a second end of the U-shaped structure is used to contact the upper mold of the hot mold during the plastic-encapsulating.

13. The electronic packaging module according to claim 12, characterized in that,
a top end of the second end of the metal component is provided with a bending section for contacting the upper mold of the hot mold during the plastic-encapsulating.

14. The electronic packaging module according to claim 12, characterized in that,
a corner radius between the first end of the metal component and a wall is less than 0.2 mm.

15. The electronic packaging module according to claim 10, characterized in that,
a wall thickness of the metal component is 50-300 um.

16. The electronic packaging module according to claim 10, characterized in that,
an end for soldering or welding, which connects the metal component and the substrate, is provided with a bending structure, and a radius of the bending structure of the end for soldering or welding is greater than a wall thickness of the metal component.

17. The electronic packaging module according to claim 10, characterized in that,
the metal component is a metal column or a metal wall.

18. The electronic packaging module according to claim 17, characterized in that,
an interior of the metal column or the metal wall is hollow.

19. The packaging method according to claim 1, characterized in that,
the substrate comprises a ground pin, and the metal component is electrically connected to the ground pin.

20. The electronic packaging module according to claim 10, characterized in that,
the substrate comprises a ground pin, and the metal component is electrically connected to the ground pin.
